(19) United States
(12) Patent Application Publication
(10) Pub. No.: US 2009/0079042 A1
(43) Pub. Date: Mar. 26, 2009

(54) Center Conductor to Integrated Circuit for High Frequency Applications

(75) Inventors: Jim Clatterbaugh, Santa Rosa, CA (US); Hassan Tanbakuchi, Santa Rosa, CA (US); Matthew R. Richter, Santa Rosa, CA (US); Michael B. Whitener, Santa Rosa, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(73) Assignee: AGILENT TECHNOLOGIES, INC., Loveland, CO (US)

(21) Appl. No.: 11/858,911

(22) Filed: Sep. 21, 2007

(51) Int. Cl. H01L 23/48; H01L 21/44

(52) U.S. Cl. 257/664; 438/613; 257/E23.01; 257/E21.476

(57) ABSTRACT

A microcircuit has a node thereon. A center conductor is electrically connected to the node and the center conductor has a length to minimum radius ratio of at least 50. A method of for providing electrical interconnections in a microcircuit, comprises the steps of depositing conductive bumps on the microcircuit; and aligning and bonding a center conductor to the conductive bumps, the center conductor having a first end and a second end, and the center conductor having a length to minimum radius ratio of at least 50.

### BACKGROUND OF THE INVENTION

An interconnect is a conduit for passing an electrical signal from one device to another, for example an integrated circuit to an external device. The most widely used interconnect is a wire bond. Interconnects include, but are not limited to, single or multiple round wires, ribbon wires and wire mesh bonds.

FIG. 1 is a diagram illustrating a microcircuit 101 with an integrated circuit 103, a transmission line 105 and interconnects 107. In this example, the interconnects 107 are wire bonds between the transmission line 105 and a pad 109 on the integrated circuit 103.

A common disadvantage of a wire bond is its parasitic inductance. The inductance is a complex and unpredictable combination of the length of the wire bond and the bonding material used to secure the wire bond to an electrical device.

In high frequency electronic applications, for example those operating in excess of 20 GHz, it is desirable to minimize the parasitic inductance of the interconnects to ensure signal integrity.

Accordingly, there is a need for an improved way to interconnect an integrated circuit to a point outside without degrading the integrity of the signal.

### BRIEF DESCRIPTION OF THE DRAWINGS

FIG. 1 is a diagram illustrating an interconnect from an integrated circuit to a transmission line common in the art;

FIGS. 2A-C are illustrations of an embodiment of the invention;

FIG. 3 is a flow chart describing a process for thermosonically bonding the center conductor of FIG. 2A onto a high frequency node; and

FIG. 4 is a diagram of a microcircuit using the center conductor of the present invention.

### DETAILED DESCRIPTION

An embodiment of the invention is an interconnect between two high frequency nodes (‘node’). The embodiment comprises a center conductor, conductive bumps, and a bonding process. As an example, the invention can replace a wire bond for connecting an electrical pad on a circuit board to an external connector. The node can be any conducting surface to which a center conductor can be bonded to. Thus the node can include a surface of the conductive bump, a surface of a electrical pad, a bonding pad or an electrical component.

The invention has the advantage of lower inductance over conventional interconnects (for example, wire bonds, ribbon wire or wire mesh bonds). This characteristic is particularly beneficial in electrical systems operating at frequencies in excess of 20 GHz. The invention also improves the consistency (compared to the prior art) of the connections between nodes, thereby lowering manufacturing costs. Additionally, unlike the prior art, shear strength of the bonds between the center conductor and the node is not compromised and does not lead to additional structural failures in the field.

In general the center conductor is elongated and can have various cross sections. For example, it can have a shape substantially resembling a circular cylinder. The elongated section of center conductor can be generally straight or have multiple bends to fit between nodes. In other embodiments, the center conductor can have a cross section resembling an ellipse, a polygon, or other shapes.

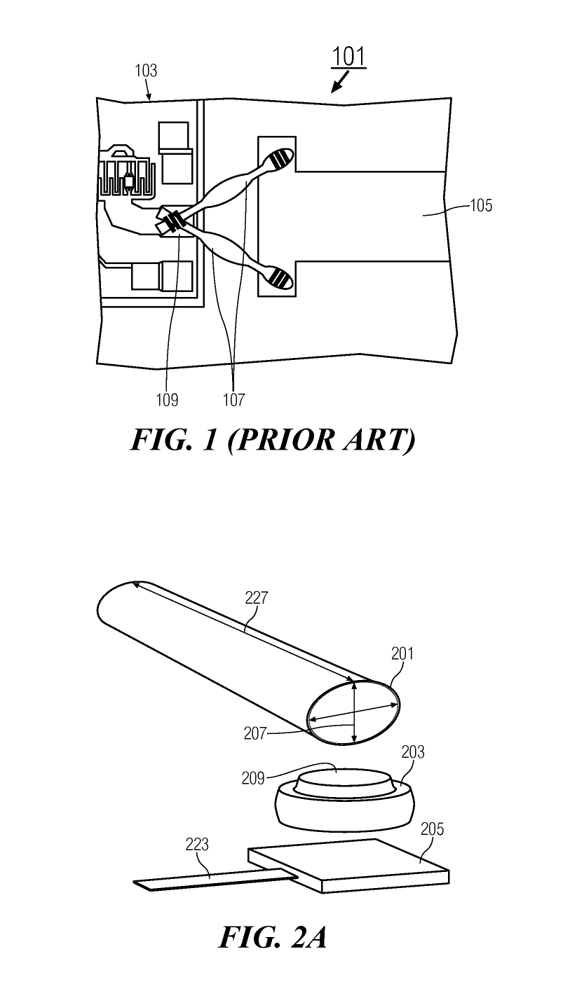

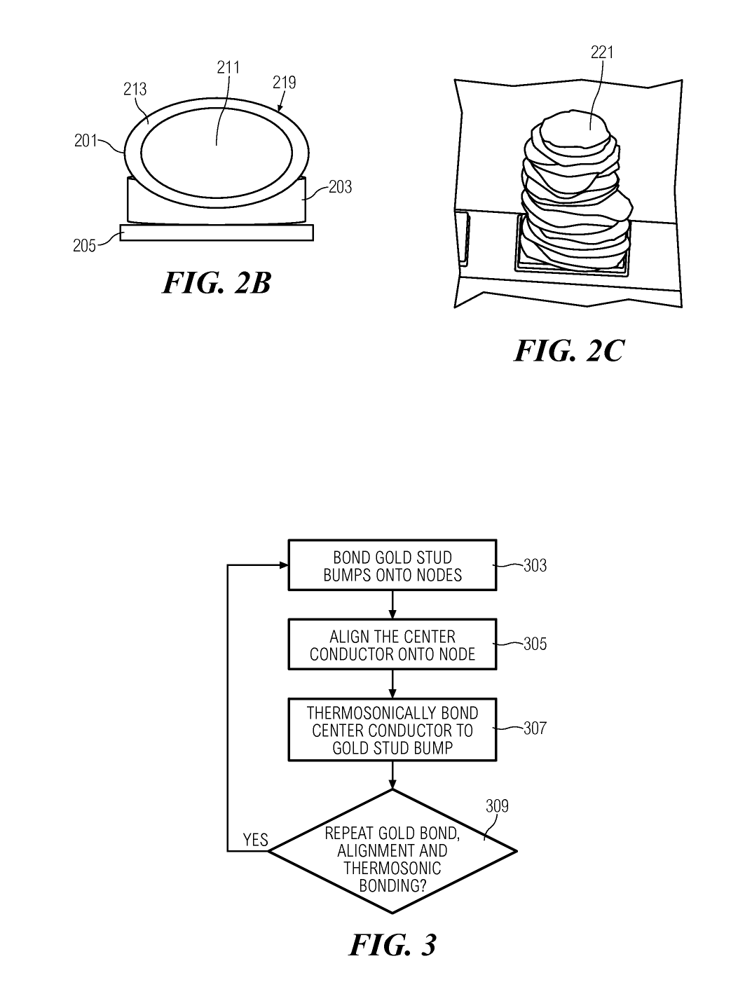

FIG. 2A is a dimetric projection of an embodiment of the invention including a center conductor 201, a stud bump 203, an electrical pad 205 (an example of a node), and a wire trace 223. In general, the stud bump can be replaced by any type of conductive bump. Examples of conductive bumps are stud bumps, solder bumps, adhesive bumps or other bumping material. A conductive bump can comprise a single stud bump or many stud bumps. Multiple stud bumps can take the form of a vertical stack. This is illustrated below.

The center conductor of this embodiment is shown with an elliptically shaped cross-section. The center conductor 201 can have a length 227 of at least a half inch and a minor axis radius 207 of approximately 10 mils or less.

Generally the ratio of the length 227 of the center conductor to the smallest (‘minimum’) radius 207 can be used to characterize the center conductor of the present invention. In the embodiment shown in FIG. 2A, the ratio of the length to the minimum radius can be at least 50. In another embodiment, the center conductor can have a length of at least one inch and a minimum radius of 10 mil or less, thereby having a ratio of at least 100. In yet another embodiment, the center conductor can have a minimum ratio of 0.007 inches (7 mils) or less and at least an inch in length thereby having a ratio of length to minimum radius of at least 142.

FIG. 2B is a side view drawing of the center conductor 201 bonded to the electrical pad 205 using the stud bump 203. The center conductor has a core 211 made of a conductive metal and is plated with plating 213 to inhibit corrosion and improve adhesion when bonded.

In one embodiment, the core 211 can be made from brass. A brass core exhibits low Young's Modulus (a measure of the stiffness of a given material) and allows for deformation (Plastic Region) at low stress levels. In addition, a brass core is able to withstand a heat-treated bonding process. These advantages result in fewer tension-induced pull failures at the interconnect and subsequently lower failures in the field.

In other embodiments the core 211 can be made from beryllium copper or other materials.

The plating 213 of the center conductor can be made of Type III Class A gold purity. In one embodiment, soft bondable gold of at least 50 microinches can be used to plate the center conductor. At frequencies in excess of 20 GHz, gold plating reduces ‘skin effect’ on non-plated conductors. Skin effect generally leads to a loss of signal integrity.

FIG. 2C is a drawing of stud bumps 203 stacked on top of each other. This stacked stud bump 221 creates a raised effect to aid in vertically aligning the center conductor onto the node. Two advantages arise from this embodiment. First, an ability to adhere to a node with poor adhesion properties. This results in a stronger bond and mitigates the problem of cratering on the node when the center conductor is pulled off the node abruptly. The second advantage is an improved flexibility when bonded to a center conductor of high Young's Modulus. This has a positive effect on the coefficient of thermal expansion.

The overall bonding process can comprise two stages. In the example of the center conductor being affixed to the electrical pad 205 (in FIG. 2A or 2B), the first stage requires bonding the stud bump 203 to the electrical pad 205. In the second stage, the center conductor 201 is bonded to the stud bump 203. Alternatively, the center conductor can be bonded directly to an electrical pad that is fitted with a conductive bump or conductive material, thereby requiring a one stage bonding process.

Bonding the center conductor to the stud bump is accomplished by a thermosonic process (described in detail below). This process maintains the cross-sectional properties of the center conductor when bonded (reference numeral 219 of FIG. 2B) and reduces the inductance at the interconnect. Thermosonic bonding has the following advantages: (i) metallurgical bonds are more reliable than conductive particles and adhesive joining (ii) process cycle time can be reduced significantly and (iii) lower manufacturing cost per unit.

FIG. 3 is a flow chart illustrating a method of bonding using the thermosonic process on the gold stud bumps. In block 303, a stud bump or multiple stud bumps are bonded onto nodes; for example on a circuit board designed to support center conductors as interconnects. The stud bumps are coined using a standard tamping tool to provide a flat surface to facilitate placement of the center conductor.

A 2460-V Palomar automated ball bonder or a MEI Thermosonic ball bonder are examples of a ball bonders that will facilitate the ball bond process and the coining off process of the stud bump embodiment. The Mechel bonder modifications results in a 2.5 mil free air ball and a 3.5 mil wide 1.2 mil high bonded ball with a 35% aspect ratio.

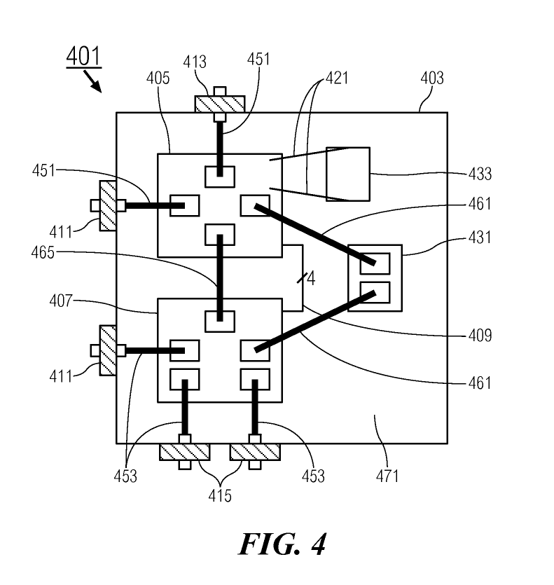

In block 305, center conductors are placed onto the nodes (with stud bumps already bonded thereon). The center conductor rests within the confines of the stud bump. This requires aligning the center conductor within +/−0.5 mil placement accuracy of the center of the stud bump in a horizontal plane 209 of the node as illustrated in FIG. 2A. This horizontal plane is parallel to the horizontal plane 471 of a circuit board 403 of FIG. 4 (described later). Alignment in the plane perpendicular to the circuit board 403 of FIG. 4 (described later), requires placement of the center conductor resulting in physical contact with the stud bump with 0.5-1.0 mil overtravel. Overtravel is defined by continued pressure after physical contact between the center conductor and the stud bump. In this instance, the engagement is extended for a finite distance of 0.5-1.0 mil.

A bond tool with a 3.2 by 10 mil tungsten carbide wedge foot and a 90-degree electrical discharge machining (EDM) groove cut into a bond tip is an example of a bonding tool. The bond tool is capable of transferring ultrasonic energy through the center conductor and into the stud bump attached to the node.

The circuit board is then sent into a thermosonic assembly to electrically connect the center conductors to the gold stud bumps and pads (block 307).

The thermosonic process is set to ambient temperature, 100 gram force, 16 microinches of transducer excursion and 300 milliseconds of bond time. This results in an electrical connection from the node to the center conductor.

The steps in blocks 303-307 are repeated for the remaining center conductors (block 309).

A center conductor aligned within the requirements described above will bond to the stud bump in a desired form 219 in FIG. 2B. In FIG. 2B, the center conductor 201 is bonded to the stud bump 203 and retains its cross-sectional properties. The center conductor rests on the stud bump, which in turn is supported by the electrical pad 205. The electrical pad provides a permanent connection to the underlying wire trace 223 of FIG. 2A.

This shear strength derived from a thermosonic bond is equal in magnitude to that of a wire bonding process. Destructive pull tests conducted on a bonded center conductor (using the method embodiment described in FIG. 3) results in a residual nugget residing on the node or a residual nugget residing on the center conductor. The shear strength test results exceed the American Society for Testing and Materials (ASTM) standards.

The stud bump may be bonded to the node using either a manual or an automated process. In the case of an integrated circuit, the stud bump can be bonded to a pad on the integrated circuit either while it is still part of a wafer, or after the wafer is diced into individual circuits. Alternatively, the integrated circuit may be fabricated to include the stud bumps, in which case subsequent bonding of the stud bumps to the pad is not needed. Similarly, alignment of the center conductor onto a node may be performed manually or accomplished by automated equipment. Likewise, the center conductor to stud bump bonding may be either a manual or automated thermosonic process.

FIG. 4 is a simplified block diagram (not to scale) illustrating an aspect of the present invention. A microcircuit 401 includes a circuit board 403 housing integrated circuits 405 and 407, external connectors 411-415, transmission lines 409, single wire bonds 421 and passive components 431 and 433.

In this simplified illustration of the microcircuit, the integrated circuits are interconnected with a bus of four transmission lines 409 to carry lower frequency signals, for example control signals. The wire bonds 421 can also connect the passive component 433, e.g. a capacitor or resistor, to the integrated circuit 405.

A high frequency signal can pass between the integrated circuits and the passive component 431 through the center conductors 461. External connectors 411-415 provide external access to the integrated circuits and other components, and are connected to various parts of the microcircuit using center conductors 451 and 453. Direct connectivity between integrated circuits 405 and 407 is provided for by center conductor 465.

While the embodiments described above constitute exemplary embodiments of the invention, it should be recognized that the invention can be varied in numerous ways without departing from the scope thereof. It should be understood that the invention is only defined by the following claims.

1. A microcircuit having a node thereon, comprising:
a center conductor electrically connected to the node wherein the center conductor has a length to minimum radius ratio of at least 50.

2. The microcircuit of claim 1 wherein the center conductor is bonded to the node.

3. The microcircuit of claim 2 wherein the center conductor is bonded to the node using a thermosonic process.

4. The microcircuit of claim 1, further comprising a conductive bump bonded to a bonding pad of the microcircuit and wherein the node is on the conductive bump.

5. The microcircuit of claim 4, wherein the conductive bump comprises a plurality of stacked stud bumps.

6. The microcircuit of claim 1, wherein the center conductor contains a conductive core of a first metal and is plated with a second metal.

7. The microcircuit of claim 1, wherein the length of the center conductor is at least a half inch.

8. The microcircuit of claim 5, wherein the plurality of stacked stud bumps are composed of gold metal.

9. A method of for providing electrical interconnections in a microcircuit, comprising the steps of:
depositing conductive bumps on the microcircuit; and
aligning and bonding a center conductor to the conductive bumps, the center conductor having a first end and a second end, and the center conductor having a length to minimum radius ratio of at least 50.

10. The method of claim 9, wherein the conductive bumps comprise a first node and a second node.

11. The method of claim 9, wherein bonding is a thermosonic process.

12. The method of claim 9, wherein depositing conductive bumps comprises depositing a stud bump.

13. The method of claim 9, wherein depositing conductive bumps comprises depositing a plurality of stacked stud bumps.

14. The method of claim 9, wherein the length of the center conductor is at least a half inch.

15. The method of claim 10, wherein aligning and bonding comprises aligning the first end of the center conductor on the first node of the conductive bumps and bonding the first end to the first node.

16. The method of claim 15, wherein aligning and bonding comprises aligning the second end of the center conductor on the second node of the conductive bumps and bonding the second end to the second node.

17. The method of claim 10, wherein aligning comprises placing the first end of the center conductor on the first node of the conductive bumps, and placing the second end of the center conductor on the second node of the conductive bumps.

18. The method of claim 9, wherein the center conductor is composed of a conductive core and a metallic plating.

19. The method of claim 12, wherein the stud bump is composed of gold metal.
